(19) United States
(12) Patent Application Publication
(10) Pub. No.: US 2025/0023322 A1
(43) Pub. Date: Jan. 16, 2025

(54) LASER SOURCE AND LASER PROJECTION APPARATUS

(71) Applicant: HISENSE LASER DISPLAY CO., LTD, Qingdao (CN)

(72) Inventors: Xianglai PANG, Qingdao (CN); Longfei SHI, Qingdao (CN); Yali LIU, Qingdao (CN)

(73) Assignee: HISENSE LASER DISPLAY CO., LTD, Qingdao (CN)

(21) Appl. No.: 18/902,459

(22) Filed: Sep. 30, 2024

Related U.S. Application Data
(63) Continuation of application No. PCT/CN2022/137468, filed on Dec. 8, 2022.

(30) Foreign Application Priority Data
Mar. 31, 2022 (CN) 202210346829.1
Mar. 31, 2022 (CN) 202220775960.5

(51) Int. Cl. H01S 5/023; G03B 21/20; H01S 5/02216; H01S 5/02345; H01S 5/40; H05K 1/14

(52) U.S. Cl. CPC H01S 5/023; G03B 21/2013; G03B 21/2033; H01S 5/02216; H01S 5/02345; H01S 5/4087; H05K 1/141

(57) ABSTRACT

A laser source and a laser projection apparatus are provided. The laser source includes a laser assembly. The laser assembly includes a mounting substrate, a light-emitting group, and a conductive connecting portion. The mounting substrate is a first printed circuit board and includes a first surface, a first region, and a second region. The first region and the second region are discontinuously distributed, and the first region is connected with the second region through an internal wiring of the mounting substrate. The light-emitting group is electrically connected with the first region. A first end of the conductive connecting portion is connected with the second region, and a second end of the conductive connecting portion is configured to be electrically connected with a second printed circuit board, so as to electrically connect the light-emitting group with the second printed circuit board.

### CROSS-REFERENCE TO RELATED APPLICATIONS

This application is a continuation application of International Patent Application No. PCT/CN2022/137468, filed on Dec. 8, 2022, which claims priority to Chinese Patent Application No. 202210346829.1, filed on Mar. 31, 2022; and Chinese Patent Application No. 202220775960.5, filed on Mar. 31, 2022, which are incorporated herein by reference in their entireties.

### TECHNICAL FIELD

The present disclosure relates to the field of laser projection technologies and, in particular, to a laser source and a laser projection apparatus.

### BACKGROUND

With the popularization and application of laser projection apparatus, consumers have a gradually increasing demand for miniaturized laser projection apparatus. In order to achieve the miniaturization of the laser projection apparatus, not only the basic illumination functions will be achieved in the design of laser source products, but also many aspects such as volume, cost, and optical efficiency may be considered.

### SUMMARY

In an aspect, a laser source is provided. The laser source includes at least one laser assembly. The laser assembly includes a mounting substrate, at least one light-emitting group, and at least one conductive connecting portion. The mounting substrate is a first printed circuit board (PCB) and includes a first surface, a first region, and a second region. The first region and the second region are located on the first surface. The first region and the second region are discontinuously distributed, and the first region is connected with the second region through an internal wiring of the mounting substrate. The light-emitting group is disposed on the first surface and located in the first region. The light-emitting group is electrically connected with the first region and includes a plurality of light-emitting chips. The light-emitting group is configured to emit laser beams. A first end of the conductive connecting portion is connected with the second region, and a second end of the conductive connecting portion is configured to be electrically connected with a second printed circuit board, so as to electrically connect the light-emitting group with the second printed circuit board.

In another aspect, a laser projection apparatus is provided. The laser projection apparatus includes a laser source, a light modulation assembly, a projection lens, and a main board. The laser source is configured to emit illumination beams. The light modulation assembly is configured to modulate the illumination beams emitted by the laser source, so as to obtain projection beams. The projection lens is configured to project the projection beams into an image. The main board is configured to transmit a control signal, so as to control the laser projection apparatus for image display. The laser source includes a housing and a laser assembly. The laser assembly is disposed on the housing, and a light-emitting side of the laser assembly is towards an interior of the housing. The laser assembly includes a mounting substrate, a light-emitting group, and a conductive connecting portion. The mounting substrate is a first printed circuit board and includes a first surface, a first region, and a second region. The first surface is a surface of the mounting substrate proximate to the housing. The first region and the second region are located on the first surface. The first region and the second region are discontinuously distributed, and the first region is connected with the second region through an internal wiring of the mounting substrate. The light-emitting group is disposed on the first surface and located in the first region. The light-emitting group is electrically connected with the first region. The light-emitting group includes a plurality of light-emitting chips and is configured to emit laser beams. A first end of the conductive connecting portion is connected with the second region, and a second end of the conductive connecting portion is configured to be electrically connected with a second printed circuit board, so as to electrically connect the light-emitting group with the main board.

### BRIEF DESCRIPTION OF THE DRAWINGS

FIG. 1 is a diagram showing a structure of a laser source in the related art;

FIG. 2A is a diagram showing a structure of a laser assembly in the related art;

FIG. 2B is a diagram showing an interior structure of the laser assembly in FIG. 2A;

FIG. 3 is a diagram showing a structure of a laser projection apparatus, in accordance with some embodiments;

FIG. 4 is a diagram showing another structure of a laser projection apparatus, in accordance with some embodiments;

FIG. 5 is a diagram showing a beam path of a laser source, a light modulation assembly, and a projection lens in a laser projection apparatus, in accordance with some embodiments;

FIG. 6 is a diagram showing a principle of projection imaging by a laser projection apparatus, in accordance with some embodiments;

FIG. 7 is a diagram showing an arrangement of micromirrors in a digital micromirror device, in accordance with some embodiments;

FIG. 8 is a diagram showing a structure of a laser source, in accordance with some embodiments;

FIG. 9 is an exploded view of a laser source, in accordance with some embodiments;

FIG. 10 is a diagram showing a structure of a housing of a laser source, in accordance with some embodiments;

FIG. 11 is a diagram showing a structure of a laser assembly and a connecting board in a laser source, in accordance with some embodiments;

FIG. 12 is a diagram showing a structure of a laser assembly, in accordance with some embodiments;

FIG. 13 is a diagram showing a structure of a connecting board in a laser source, in accordance with some embodiments;

FIG. 14 is a diagram showing another structure of a laser assembly and a connecting board in a laser source, in accordance with some embodiments;

FIG. 15 is a sectional view of FIG. 14;

FIG. 16 is a diagram showing yet another structure of a laser assembly and a connecting board in a laser source, in accordance with some embodiments;

FIG. 17 is a sectional view of FIG. 16;

FIG. 18 is a diagram showing yet another structure of a laser assembly and a connecting board in a laser source, in accordance with some embodiments;

FIG. 19 is a diagram showing a structure of a connecting piece, in accordance with some embodiments;

FIG. 20 is a diagram showing yet another structure of a laser assembly and a connecting board in a laser source, in accordance with some embodiments;

FIG. 21 is a diagram showing yet another structure of a laser assembly and a connecting board in a laser source, in accordance with some embodiments;

FIG. 22 is a diagram showing yet another structure of a laser assembly and a connecting board in a laser source, in accordance with some embodiments;

FIG. 23 is a diagram showing a structure of another laser assembly, in accordance with some embodiments;

FIG. 24 is a diagram showing a structure of yet another laser assembly, in accordance with some embodiments;

FIG. 25A is a diagram showing yet another structure of a laser assembly and a connecting board in a laser source, in accordance with some embodiments;

FIG. 25B is a diagram showing yet another structure of a laser assembly and a connecting board in a laser source, in accordance with some embodiments; and

FIG. 26 is a diagram showing a structure of another laser source, in accordance with some embodiments.

### DETAILED DESCRIPTION

Some embodiments of the present disclosure will be clearly and completely described below with reference to the accompanying drawings. However, the described embodiments are merely some, but not all embodiments of the present disclosure. All other embodiments obtained by a person of ordinary skill in the art based on embodiments of the present disclosure shall be included in the protection scope of the present disclosure.

Unless the context requires otherwise, throughout the description and the claims, the term “comprise” and other forms thereof such as the third-person singular form “includes” and the present participle form “comprising” are construed as an open and inclusive meaning, i.e., “including, but not limited to.” In the description, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only and are not to be construed as indicating or implying the relative importance or implicitly indicating the number of indicated technical features. Thus, features defined by “first” or “second” may explicitly or implicitly include one or more of the features. In the description of the embodiments of the present disclosure, the term “a plurality of” or “the plurality of” means two or more unless otherwise specified.

In the description of some embodiments, the term “connected” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The embodiments disclosed herein are not necessarily limited to the content herein.

The phrase “at least one of A, B, and C” has the same meaning as the phrase “at least one of A, B, or C,” both including the following combinations of A, B, and C: only A, only B, only C, a combination of A and B, a combination of A and C, a combination of B and C, and a combination of A, B, and C.

The use of the phase “applicable to” or “configured to” herein means an open and inclusive expression, which does not exclude devices that are applicable to or configured to perform additional tasks or steps.

The terms such as “about,” “substantially,” and “approximately” as used herein include a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system).

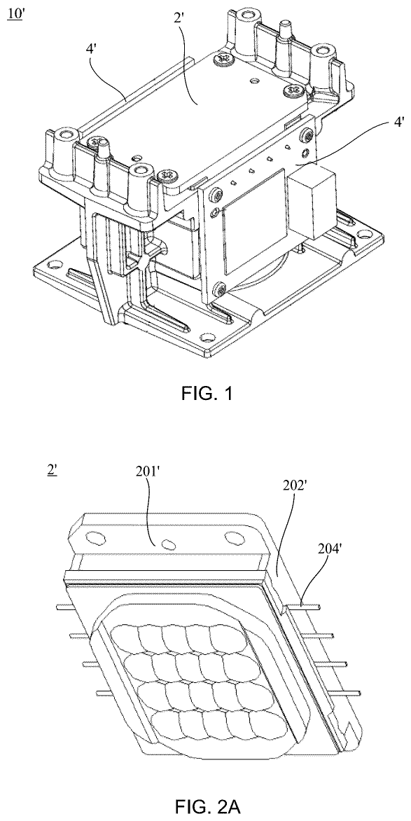

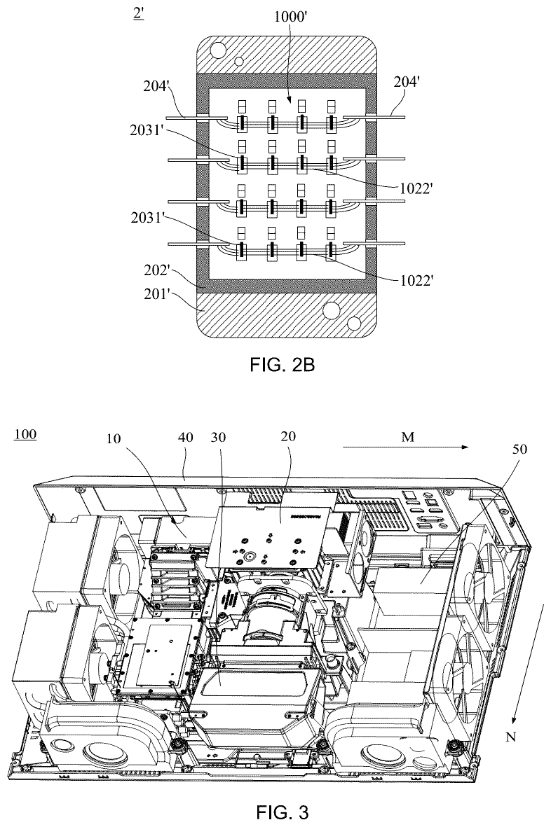

FIG. 1 is a diagram showing a structure of a laser source in the related art. FIG. 2A is a diagram showing a structure of a laser assembly in the related art. FIG. 2B is a diagram showing an interior structure of the laser assembly in FIG. 2A.

Generally, as shown in FIG. 1, the laser source 10′ includes a laser assembly 2′ and two connecting circuit boards 4′. The laser assembly 2′ includes a multi-chip laser (MCL). The two connecting circuit boards 4′ are disposed on two sides of the laser assembly 2′, respectively, and the two connecting circuit boards 4′ are perpendicular to the laser assembly 2′.

As shown in FIGS. 2A and 2B, the laser assembly 2′ includes a substrate 201′, a frame 202′, a plurality of light-emitting chips 2031′, and conductive pins 204′. The frame 202′ is disposed on the substrate 201′ and surrounds the plurality of light-emitting chips 2031′. The substrate 201′ and the frame 202′ form an accommodating space 1000′. The plurality of light-emitting chips 2031′ are disposed on the substrate 201′ and located in the accommodating space 1000′. The conductive pins 204′ are fixed to the frame 202′. First ends of conductive pins 204′ are located in the accommodating space 1000′ and connected with the plurality of light-emitting chips 2031′ by wires 1022′, and second ends of conductive pins 204′ are located outside the frame 202′ and connected with the connecting circuit boards 4′.

In this way, the connecting circuit boards 4′ may be electrically connected to the laser assembly 2′ through the conductive pins 204′, so as to transmit a signal to make the light-emitting chips 2031′ emit laser beams. However, the packaging manner causes a large volume of the laser source 10′, resulting in the large volume of the laser projection apparatus, which is not conducive to the miniaturization of the laser projection apparatus.

To this end, a laser source and a laser projection apparatus 100 using the laser source are provided in some embodiments of the present disclosure. Examples of the laser projection apparatus 100 provided in some embodiments of the present disclosure are first described below, as shown in FIG. 3.

FIG. 3 is a diagram showing a structure of a laser projection apparatus, in accordance with some embodiments. As shown in FIG. 3, the laser projection apparatus 100 includes an apparatus housing 40 (only a portion of the apparatus housing 40 being shown in FIG. 3), and a laser source 10, a light modulation assembly 20, and a projection lens 30 that are assembled in the apparatus housing 40. The laser source 10 is configured to provide illumination beams (e.g., laser beams). The light modulation assembly 20 is configured to modulate the illumination beams provided by the laser source 10 with image signals, so as to obtain projection beams. The projection lens 30 is configured to project the projection beams into an image on a screen or a wall.

The laser source 10, the light modulation assembly 20, and the projection lens 30 are sequentially connected in a propagation direction of beams, and each is wrapped by a corresponding housing. The housings of the laser source 10, the light modulation assembly 20, and the projection lens 30 support their corresponding optical components, respectively, and make the optical components meet certain sealing or airtight requirements.

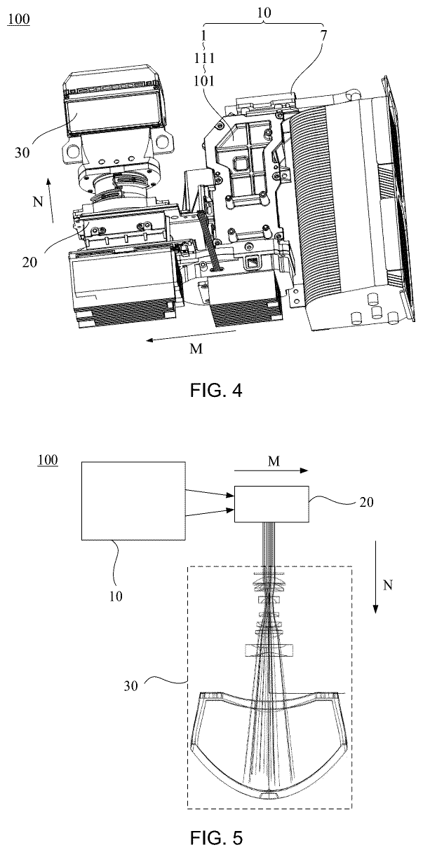

FIG. 4 is a diagram showing another structure of a laser projection apparatus, in accordance with some embodiments. As shown in FIG. 4, a first end of the light modulation assembly 20 is connected to the laser source 10, and the laser source 10 and the light modulation assembly 20 are arranged in an exit direction (referring to the direction M shown in FIG. 4) of the illumination beams of the laser projection apparatus 100. A second end of the light modulation assembly 20 is connected to the projection lens 30, and the light modulation assembly 20 and the projection lens 30 are arranged in an exit direction (referring to the direction N shown in FIG. 4) of the projection beams of the laser projection apparatus 100. The exit direction M of the illumination beams is substantially perpendicular to the exit direction N of the projection beams. In one aspect, such connecting structure may adapt to characteristics of a beam path of a reflective light valve in the light modulation assembly 20, and in another aspect, it is also conducive to shortening a length of a beam path in a one-dimensional direction, which is helpful for structural arrangement of the apparatus. For example, in a case where the laser source 10, the light modulation assembly 20, and the projection lens 30 are disposed in a one-dimensional direction (e.g., the direction M), the length of the beam path in the one-dimensional direction is long, which is not conducive to the structural arrangement of the laser projection apparatus 100. The reflective light valve will be described below.

In some embodiments, the laser source 10 may sequentially provide beams of three primary colors (beams of other colors may also be added on a basis of the beams of the three primary colors). Due to a phenomenon of visual perception of human eyes, what the human eyes see is white beams formed by mixing the beams of three primary colors. Alternatively, the laser source 10 may also simultaneously output the beams of three primary colors, so as to continuously emit the white beams. The laser source 10 may include at least one laser assembly that may emit laser beams of at least one color, such as red laser beams, blue laser beams, or green laser beams.

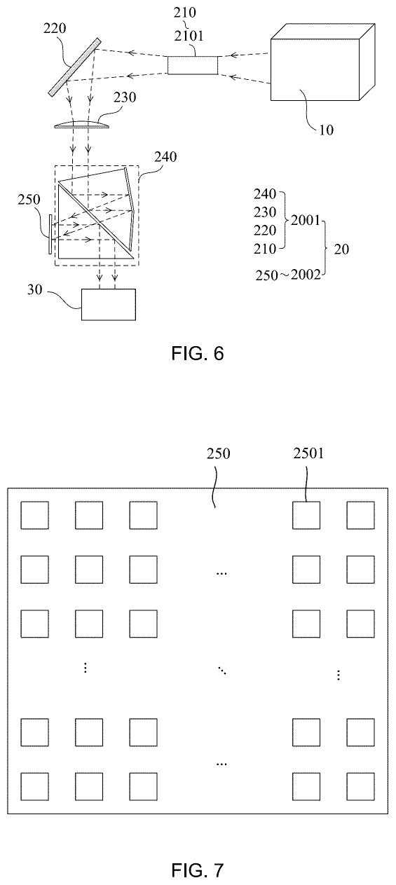

FIG. 5 is a diagram showing a beam path of a laser source, a light modulation assembly, and a projection lens in a laser projection apparatus, in accordance with some embodiments. FIG. 6 is a diagram showing a principle of projection imaging by a laser projection apparatus, in accordance with some embodiments.

The illumination beams emitted by the laser source 10 enter the light modulation assembly 20. As shown in FIGS. 5 and 6, the light modulation assembly 20 includes an illumination lens group 2001 and a light modulation device (or the light valve) 2002. The illumination lens group 2001 is configured to receive the illumination beams provided by the laser source 10 and propagate the illumination beams to the light modulation device 2002 at a set angle and direction. The light modulation device 2002 is configured to modulate the illumination beams to obtain the projection beams and reflect the projection beams into the projection lens 30.

In some embodiments, as shown in FIG. 6, the illumination lens group 2001 includes a homogenizing component 210, a lens component 230, and a prism group 240. The homogenizing component 210 is configured to receive the illumination beams provided by the laser source 10 and homogenize the illumination beams. The lens component 230 is configured to converge the illumination beams exiting from the homogenizing component 210 onto the prism group 240. The prism group 240 is configured to reflect the illumination beams to the light modulation device 2002.

In some embodiments, as shown in FIG. 6, the homogenizing component 210 includes a light pipe 2101. A light outlet of the light pipe 2101 may be in a shape of a rectangle, so as to have a shaping effect on a beam spot. In this way, the shape of the beam spot of the illumination beams exiting from the light pipe 2101 may match a rectangular laser-receiving surface of the light modulation device 2002. Alternatively, the homogenizing component 210 may include a fly-eye lens. The fly-eye lens may homogenize the incident illumination beams and shape the illumination beams, so as to output a rectangular beam spot.

In some embodiments, as shown in FIG. 6, the illumination lens group 2001 further includes a reflector 220. The reflector 220 is located on a laser-exit side of the homogenizing component 210 and configured to reflect the illumination beams exiting from the homogenizing component 210 to the lens component 230. It may be understood that the reflector 220 may also be disposed between the lens component 230 and the prism group 240, so as to reflect the illumination beams exiting from the lens component 230 to the prism group 240.

In some embodiments, as shown in FIG. 6, the light modulation device 2002 includes a digital micromirror device (DMD) 250.

In the light modulation assembly 20, the DMD 250 is configured to use an image signal to modulate the illumination beams provided by the laser source 10. That is to say, the digital micromirror device 250 controls the projection beams to display different luminance and gray scales according to different pixels in a projection image to be displayed, so as to finally produce an optical image. Therefore, the digital micromirror device 250 may also be referred to as the light valve. Depending on whether the light modulation device (or the light valve) 2002 transmits or reflects the illumination beams, the light modulation device 2002 may be classified as a transmissive light modulation device or a reflective light modulation device. For example, the DMD 250 shown in FIG. 6 reflects the illumination beams, and thus it is the reflective light modulation device. A liquid crystal light valve transmits the illumination beams, and thus it is the transmissive light modulation device. In addition, the light modulation assembly 20 may be classified as a single-chip system, a double-chip system, or a three-chip system according to the number of the light modulation devices 2002 used in the light modulation assembly 20. The light modulation device 2002 in some embodiments of the present disclosure is the digital micromirror device 250.

FIG. 7 is a diagram showing an arrangement of micromirrors in a digital micromirror device, in accordance with some embodiments.

As shown in FIG. 7, the digital micromirror device 250 includes thousands of micromirrors 2501 that may be individually driven to rotate. These micromirrors 2501 are arranged in an array. One micromirror 2501 (e.g., each micromirror 2501) corresponds to one pixel in the projection image to be displayed. The image signals may be converted into digital codes such as 0 or 1 after being processed. The micromirrors 2501 may swing in response to these digital codes. The gray scale of each pixel in a frame of an image is achieved according to durations of each micromirror 2501 in an ON state and an OFF state. In this way, the digital micromirror device 250 may modulate the illumination beams, thereby displaying the projection image. The ON state of the micromirror 2501 is a state that the micromirror 2501 is in and may be maintained when the illumination beams emitted by the laser source 10 may enter the projection lens 30 after being reflected by the micromirror 2501. The OFF state of the micromirror 2501 is a state that the micromirror 2501 is in and may be maintained when the illumination beams emitted by the laser source 10 do not enter the projection lens 30 after being reflected by the micromirror 2501.

The homogenizing component 210, the reflector 220, and the lens component 230 at a front end of the DMD 250 form an illumination path, and the illumination beams emitted by the laser source 10 have a beam size and an incident angle satisfying the requirements of the DMD 250 after passing through the illumination path.

In some embodiments, as shown in FIG. 5, the projection lens 30 includes a combination of a plurality of lenses, which are usually divided by groups, and are divided into a three-segment combination including a front group, a middle group, and a rear group, or a two-segment combination including a front group and a rear group. The front group is a lens group proximate to a laser-exit side (i.e., a side of the projection lens 30 away from the light modulation assembly 20 in the direction N in FIG. 5) of the laser projection apparatus 100, and the rear group is a lens group proximate to a laser-exit side (i.e., a side of the projection lens 30 proximate to the light modulation assembly 20 in the opposite direction of the direction N in FIG. 5) of the light modulation assembly 20. The projection lens 30 may include a zoom projection lens, or a prime focus-adjustable projection lens, or a prime projection lens.

In some embodiments, the laser projection apparatus 100 is an ultra-short-focus projection apparatus, and the projection lens 30 is an ultra-short-focus projection lens. A projection ratio of the projection lens 30 is usually less than 0.3, such as 0.24. In a case of a same projection distance, the less the projection ratio, the larger the projection image of the laser projection apparatus 100. The ultra-short-focus projection lens with a lesser projection ratio may adapt to a narrow space while ensuring the projection effect. In this way, the laser projection apparatus 100 may display a large-sized projection image with a lesser projection ratio.

In some embodiments, the projection lens 30 includes a refractor group and a reflector. The projection lens 30 may reflect the projection beams to a projection screen for imaging after correcting and magnifying the projection beams.

As shown in FIG. 3, the laser projection apparatus 100 further includes a power system architecture 50. FIG. 3 shows an exemplary position of the power system architecture 50, and the specific position of the power system architecture 50 may be arranged differently in different laser projection apparatus 100. The power system architecture 50 includes a plurality of printed circuit board assemblies (PCBA), such as a power board, a television (TV) board, a control board, and a display board. The above multiple circuit boards are usually stacked. It will be noted that one of the multiple circuit boards is a main board 500 (as shown in FIG. 25A), and the main board 500 is configured to transmit control signals, so as to control the laser projection apparatus 100 for image display.

The laser source 10 in some embodiments of the present disclosure is described in detail below.

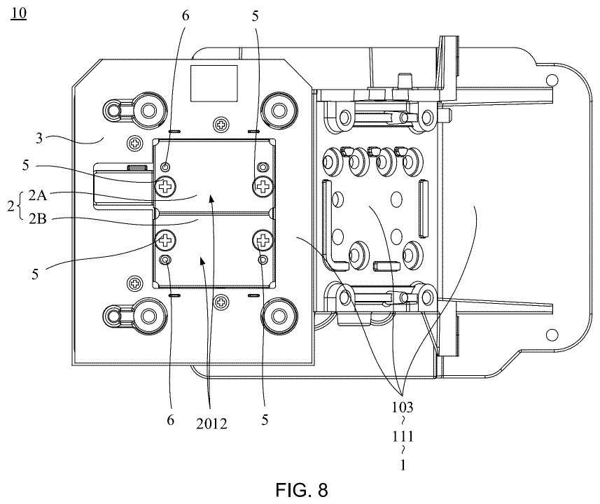

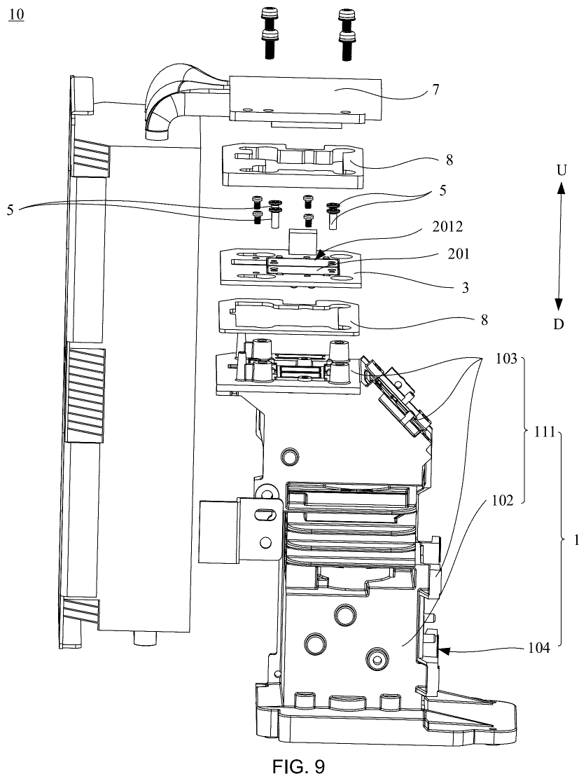

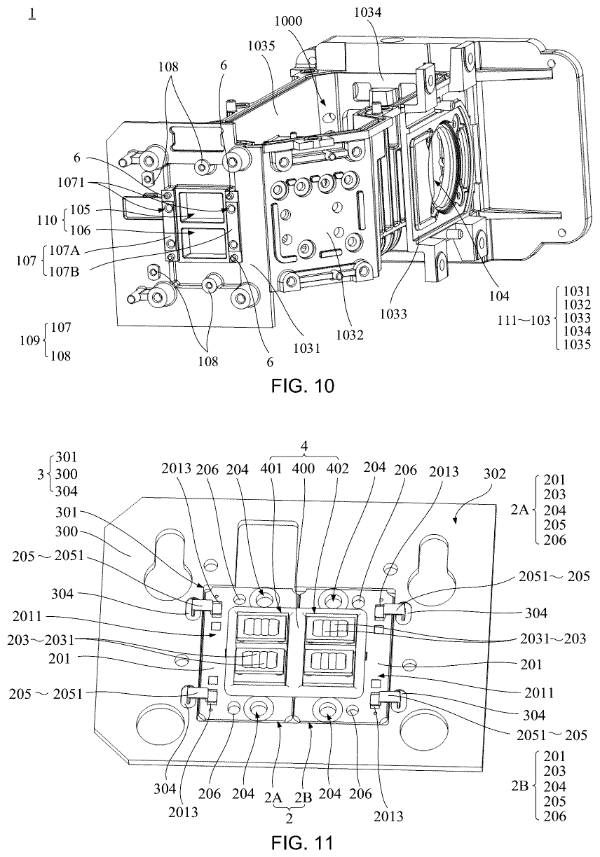

FIG. 8 is a diagram showing a structure of a laser source, in accordance with some embodiments. FIG. 9 is an exploded view of a laser source, in accordance with some embodiments. FIG. 10 is a diagram showing a structure of a housing of a laser source, in accordance with some embodiments.

In some embodiments, as shown in FIG. 8, the laser source 10 includes a housing 1 and a laser assembly 2, and the laser assembly 2 is disposed on the housing 1. The housing 1 is configured to support the optical components of the laser source 10 and to make the optical components meet set sealing or airtight requirements. The laser assembly 2 is configured to emit laser beams.

For example, as shown in FIG. 9, the housing 1 includes a housing body 111 and a light outlet 104. The housing body 111 includes a first side plate 101 (as shown in FIG. 4), a second side plate 102, and a plurality of third side plates 103. The first side plate 101 and the second side plate 102 are disposed opposite to each other. The plurality of third side plates 103 are disposed between the first side plate 101 and the second side plate 102 and connected to the first side plate 101 and the second side plate 102. The first side plate 101, the second side plate 102, and the plurality of third side plates 103 are enclosed to form an accommodating space 1000 (as shown in FIG. 10). As shown in FIG. 8, the laser assembly 2 is disposed on one of the plurality of third side plates 103. As shown in FIG. 10, the light outlet 104 is disposed on another third side plate 103 of the plurality of third side plates 103 and communicated with the accommodating space 1000 and a light inlet of the light modulation assembly 20, so that the illumination beams exiting from the laser source 10 are incident on the light modulation assembly 20.

In some embodiments, the third side plate 103 where the light outlet 104 is located may be disposed opposite to the third side plate 103 where the laser assembly 2 is located. Alternatively, the third side plate 103 where the light outlet 104 is located may be perpendicular to the third side plate 103 where the laser assembly 2 is located. For example, as shown in FIG. 10, the plurality of third side plates 103 include a first side sub-plate 1031, a second side sub-plate 1032, a third side sub-plate 1033, a fourth side sub-plate 1034, and a fifth side sub-plate 1035. Two adjacent side sub-plates of the first side sub-plate 1031, the second side sub-plate 1032, the third side sub-plate 1033, the fourth side sub-plate 1034, and the fifth side sub-plate 1035 are connected. The laser assembly 2 is disposed on the first side sub-plate 1031, and the light outlet 104 is disposed on the third side sub-plate 1033, and the third side sub-plate 1033 is perpendicular to the first side sub-plate 1031.

In some embodiments, the laser source 10 may further include a lens group and a reflecting lens group, and the lens group and the reflecting lens group are disposed in the accommodating space 1000 of the housing 1. The lens group is configured to converge and diverge the laser beams emitted by the laser assembly 2, and the reflecting lens group is configured to reflect the laser beams emitted by the laser assembly 2, so as to change the propagation path of the laser beams. It will be noted that the laser beams emitted by the laser assembly 2 are used as the illuminated beams of the laser source 10 and exit from the light outlet 104 after passing through the lens group and the reflecting lens group.

The laser source 10 is configured to emit laser beams of at least one color. For example, the laser assembly 2 emits laser beams of one color, in which case the laser source 10 is a monochromatic laser source. Of course, the laser assembly 2 may also emit laser beams of at least two colors, in which case the laser source 10 may be a two-color laser source or a multi-color laser source.

In some embodiments, the laser source 10 may include one laser assembly 2. The laser assembly 2 may emit laser beams of one color or laser beams of multiple colors. Alternatively, the laser source 10 may include a plurality of laser assemblies 2. In this case, one of the plurality of laser assemblies 2 may emit laser beams of one color, and the plurality of laser assemblies 2 may emit laser beams of a same color. Of course, the plurality of laser assemblies 2 may also emit laser beams of different colors, or each of the plurality of laser assemblies 2 may emit laser beams of at least two colors, and the present disclosure is not limited thereto.

It will be noted that in a case where the plurality of laser assemblies 2 emit laser beams of one or two colors, the laser source 10 may further include a phosphor wheel disposed in the accommodating space 1000 of the housing 1. The phosphor wheel may generate fluorescent beams of other colors due to the irradiation of the laser beams emitted by the laser assemblies 2, so as to meet the display requirements of the projection image.

FIG. 11 is a diagram showing a structure of a laser assembly and a connecting board in a laser source, in accordance with some embodiments. In some embodiments, as shown in FIG. 11, the laser assembly 2 includes a mounting substrate 201, a light-emitting group 203, and a conductive connecting portion 205. The mounting substrate 201 includes a first surface 2011 and a second surface 2012 (as shown in FIG. 8), and the first surface 2011 and the second surface 2012 are disposed opposite to each other. The first surface 2011 is a surface of the mounting substrate 201 proximate to the housing 1. The second surface 2012 is a surface of the mounting substrate 201 away from the housing 1. Of course, in some embodiments, the first surface 2011 may also be the surface of the mounting substrate 201 away from the housing 1, and the second surface 2012 may also be the surface of the mounting substrate 201 proximate to the housing 1.

In some embodiments, the mounting substrate 201 is a first printed circuit board (PCB). For example, the mounting substrate 201 includes a base, a conductive layer, and an insulating layer, and the base, the conductive layer, and the insulating layer are stacked sequentially. The base may be made of an insulating material with high thermal conductivity. The conductive layer may be made of a metal (e.g., copper). The conductive layer has a conductive pattern, and the conductive pattern is formed by means of an etching process, and the conductive connecting portion 205 is electrically connected with the light-emitting group 203 through the conductive pattern. Portions (e.g., pads) where the conductive layer is electrically connected with the light-emitting group 203 and the conductive connecting portion 205 are exposed, and the insulating layer covers other portions of the conductive layer, so as to protect the conductive layer.

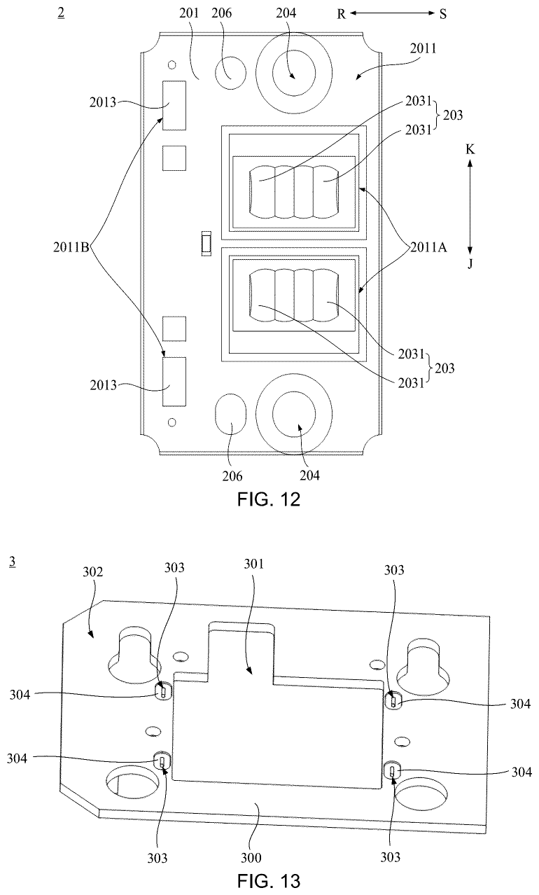

FIG. 12 is a diagram showing a structure of a laser assembly, in accordance with some embodiments. In some embodiments, as shown in FIG. 12, the mounting substrate 201 includes a first region 2011A and a second region 2011B, and the first region 2011A and the second region 2011B are located on the first surface 2011. The first region 2011A and the second region 2011B are discontinuously distributed, and the first region 2011A is connected with the second region 2011B through an internal wiring of the mounting substrate 201. For example, the first region 2011A and the second region 2011B are the portions of the conductive layer that are not covered by the insulating layer, and the first region 2011A and the second region 2011B may be connected with each other through the conductive pattern in the conductive layer.

The light-emitting group 203 is disposed on the first surface 2011 of the mounting substrate 201 and located in the first region 2011A. The light-emitting group 203 is electrically connected to the first region 2011A and configured to emit the laser beams. For example, the first region 2011A includes a third pad, and the light-emitting group 203 includes a connecting region corresponding to the first region 2011A. The connecting region is welded (e.g., brazed) with the third pad, so that the light-emitting group 203 is electrically connected to the first region 2011A.

In some embodiments, the light-emitting group 203 includes a plurality of light-emitting chips 2031. For example, as shown in FIG. 12, four light-emitting chips 2031 are packaged into one light-emitting group 203, and the four light-emitting chips 2031 are connected in series. Of course, the light-emitting group 203 may also include one, two, three, or more light-emitting chips 2031, and the present disclosure is not limited thereto.

In some embodiments, the laser assembly 2 may include one or more light-emitting groups 203. The plurality of light-emitting groups 203 may be connected in series. Alternatively, the plurality of light-emitting groups 203 may be connected in parallel.

For example, in a case where the plurality of light-emitting groups 203 emit laser beams of a same color, the plurality of light-emitting groups 203 may be connected in series. In a case where the plurality of light-emitting groups 203 emit laser beams of different colors, in the plurality of light-emitting groups 203, the light-emitting groups 203 emitting laser beams of different colors are connected in parallel, and the light-emitting groups 203 emitting laser beams of a same color are connected in series.

In some embodiments, a first end of the conductive connecting portion 205 is connected with the second region 2011B of the mounting substrate 201. A second end of the conductive connecting portion 205 is electrically connected to a second printed circuit board. The second printed circuit board may include a connecting board 3 or the main board 500. The connecting board 3 may be electrically connected to the main board 500, and the connecting board 3 will be described later. The conductive connecting portion 205 is configured to electrically connect the mounting substrate 201 with the main board 500. The light-emitting group 203 is electrically connected to the conductive connecting portion 205 through the mounting substrate 201, so that the control signals sent by the main board 500 may be transmitted to the light-emitting group 203 to control the light-emitting group 203 to emit the laser beams.

For example, as shown in FIG. 12, the mounting substrate 201 includes a first welding portion 2013, and the first welding portion 2013 constitutes the second region 2011B. The first end of the conductive connecting portion 205 is welded to the first welding portion 2013, or the conductive connecting portion 205 may also abut against the first welding portion 2013, so as to connect the conductive connecting portion 205 with the second region 2011B. In this way, the light-emitting group 203 may be electrically connected with the conductive connecting portion 205 by the conductive layer of the mounting substrate 201, and the reliability of the connection between the light-emitting group 203 and the conductive connecting portion 205 is improved.

In some embodiments, the conductive connecting portion 205 may include a connecting wire (e.g., a flexible printed circuit). A first end of the connecting wire may be connected with the second region 2011B by a socket (e.g., a first socket 2052 in FIG. 23), and a second end of the connecting wire may be electrically connected to the main board 500 by another socket (e.g., a third socket 501 in FIG. 25A). Alternatively, the conductive connecting portion 205 is electrically connected to the main board 500 through a connecting circuit board in the laser projection apparatus 100. It will be noted that the connecting circuit board may be disposed on the housing 1, so as to connect the main board 500 to the conductive connecting portion 205. Of course, the connecting circuit board may also be disposed in other positions.

In some embodiments of the present disclosure, the light-emitting group 203 and the conductive connecting portion 205 are electrically connected with each other through the conductive layer of the mounting substrate 201, so that the light-emitting group 203 may be electrically connected to the main board 500 in the laser projection apparatus 100 through the conductive connecting portion 205. In this way, the light-emitting group 203 may receive the control signals of the main board 500, so as to emit the laser beams. As a result, there is no need to provide a side plate around the mounting substrate 201 to fix the conductive connecting portion 205, and the laser assembly 2 has a small volume, which makes the overall volume of the laser source 10 small and is conducive to the miniaturization of the laser projection apparatus 100 and improves the portability of the laser projection apparatus 100.

In addition, the conductive connecting portion 205 is connected to the mounting substrate 201 by means of the surface mounted technology welding, which is conducive to the installation and disassembly between the laser assembly 2 and the housing 1 and conducive to repairing and replacing the laser assembly 2.

The connecting manners between the main board 500 and the laser assembly 2 in some embodiments of the present disclosure are described in detail below.

FIG. 13 is a diagram showing a structure of a connecting board in a laser source, in accordance with some embodiments. In some embodiments, as shown in FIG. 13, the laser source 10 further includes the connecting board 3. A layer structure of the connecting board 3 is similar to that of the mounting substrate 201. For example, the connecting board 3 is a second PCB. The connecting board 3 is electrically connected to the main board 500. For example, the connecting board 3 is provided with a fourth socket, and the fourth socket is electrically connected to the main board 500 by wires.

In some embodiments, as shown in FIG. 13, the connecting board 3 includes a board body 300 and a hollow region 301. The hollow region 301 is disposed on the board body 300 and runs through the board body 300. The laser assembly 2 is located in the hollow region 301. For example, an inner wall of the hollow region 301 is adjacent to an outer surface of the mounting substrate 201. In this way, the mounting substrate 201 is tightly connected to the connecting board 3, which improves the reliability of the connection between the mounting substrate 201 and the connecting board 3. It will be noted that the connecting board 3 may refer to the above connecting circuit board.

In some another embodiments, the connecting board 3 includes the board body 300 and an opening. For example, in a direction perpendicular to a thickness direction of the board body 300, a side of the board body 300 is concave inward to form the opening, and the laser assembly 2 is located in the opening. The following is mainly given by considering an example in which the connecting board 3 includes the hollow region 301.

In some embodiments, as shown in FIG. 11, the board body 300 has a third surface 302, and the third surface 302 is a surface of the board body 300 proximate to the housing 1. Of course, the third surface 302 may also be other surfaces of the board body 300. For example, the third surface 302 is a surface of the board body 300 away from the housing 1, and the present disclosure is not limited thereto.

The third surface 302 is flush with the first surface 2011 of the mounting substrate 201, which means that the first surface 2011 is coplanar with the third surface 302. For example, in a case where the mounting substrate 201 has the same thickness as the connecting board 3, the mounting substrate 201 and the connecting board 3 are coplanar. In this way, the laser assembly 2 and the connecting board 3 have small dimensions in the thickness direction, and the overall smoothness of the laser assembly 2 and the connecting board 3 is high after installation.

Of course, in some embodiments, the first surface 2011 and the third surface 302 may also be in different planes.

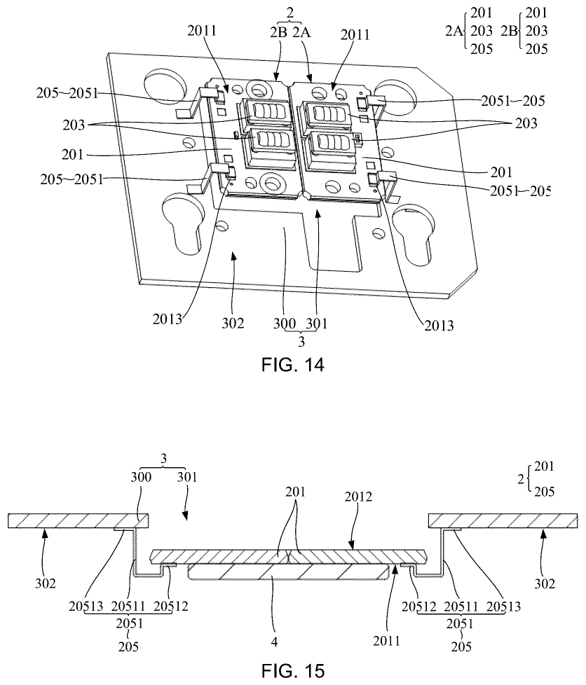

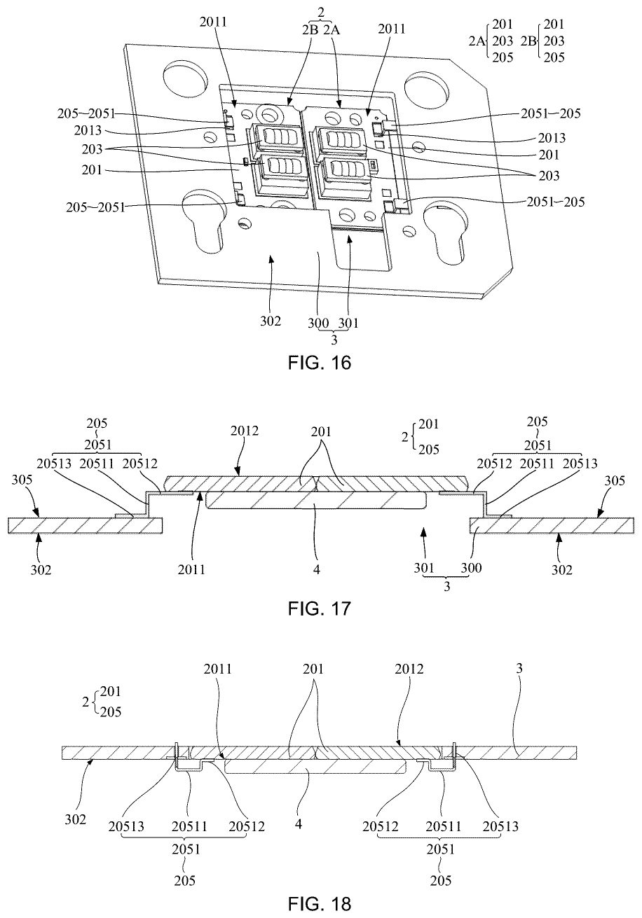

FIG. 14 is a diagram showing another structure of a laser assembly and a connecting board in a laser source, in accordance with some embodiments. FIG. 15 is a sectional view of FIG. 14. FIG. 16 is a diagram showing yet another structure of a laser assembly and a connecting board in a laser source, in accordance with some embodiments. FIG. 17 is a sectional view of FIG. 16.

For example, as shown in FIGS. 14 and 15, the connecting board 3 is located on a side (e.g., an upper side) of the mounting substrate 201 away from the light-emitting group 203, and the board body 300 of the connecting board 3 and the mounting substrate 201 are disposed at an interval.

For example, as shown in FIGS. 16 and 17, the connecting board 3 is located on a side (e.g., a lower side) of the mounting substrate 201 proximate to the light-emitting group 203, and the board body 300 of the connecting board 3 and the mounting substrate 201 are disposed at an interval. In this case, the second end of the conductive connecting portion 205 is disposed on a fourth surface 305, so as to be connected with the connecting board 3. The fourth surface 305 is a surface of the board body 300 opposite to the third surface 302.

It may be understood that the connecting board 3 and the mounting substrate 201 may also be stacked up and down or stacked down and up.

It will be noted that since the board body 300 and the mounting substrate 201 are disposed at an interval, there may be no need for the laser assembly 2 to be disposed in the hollow region 301 as long as an orthogonal projection of the laser assembly 2 on the board body 300 is located in the hollow region 301.

In addition, the hollow region 301 of the connecting board 3 is optional and may be omitted. For example, the connecting board 3 may not include the hollow region 301, and the mounting substrate 201 is arranged side by side with the connecting board 3.

For the arrangement manner between the laser assembly 2 and the connecting board 3 in a case where the connecting board 3 includes the opening, reference may be made to the arrangement manner between the laser assembly 2 and the connecting board 3 in a case where the connecting board 3 includes a hollow region 301, which will not be repeated herein.

In some embodiments, a light-emitting surface of the light-emitting group 203, the mounting substrate 201, and the connecting board 3 may be parallel to each other.

In a case where the laser source 10 includes the connecting board 3, the first end of the conductive connecting portion 205 is connected with the second region 2011B, and the second end of the conductive connecting portion 205 is connected with the connecting board 3, so that the mounting substrate 201 is connected with the connecting board 3. In this way, the control signals from the main board 500 may be transmitted to the light-emitting group 203 through the connecting board 3 and the mounting substrate 201. In addition, the second region 2011B may be located at an edge of the mounting substrate 201, and the second region 2011B is closer to the connecting board 3 than the first region 2011A, which is conducive to the installation of the conductive connecting portion 205.

In some embodiments, as shown in FIG. 11, the conductive connecting portion 205 includes a plurality of connecting pieces 2051. The connecting piece 2051 may be made of a conductive metal material and be a one-piece member. A first end of the connecting piece 2051 is disposed on the first surface 2011 and connected with the mounting substrate 201, and a second end of the connecting piece 2051 is disposed on the third surface 302 and connected with the connecting board 3.

For example, the two ends of any of the plurality of connecting pieces 2051 are rigidly connected to the mounting substrate 201 and the connecting board 3, respectively. For example, the two ends of any of the plurality of connecting pieces 2051 are connected with the mounting substrate 201 and the connecting board 3 by means of welding, respectively, and are fixed to the mounting substrate 201 and the connecting board 3, respectively.

In some embodiments, as shown in FIG. 12, the mounting substrate 201 includes a plurality of first welding portions 2013, and the plurality of first welding portions 2013 constitute the second region 2011B. The plurality of first welding portions 2013 are disposed on the first surface 2011 and electrically connected with the plurality of light-emitting chips 2031 of the light-emitting group 203. In this case, as shown in FIGS. 11 and 13, the connecting board 3 includes a plurality of second welding portions 304. The plurality of second welding portions 304 are disposed on the board body 300 (e.g., the third surface 302) and correspond to the plurality of first welding portions 2013.

For example, in a case where the mounting substrate 201 includes two first welding portions 2013, the connecting board 3 includes two second welding portions 304, and the conductive connecting portion 205 includes two connecting pieces 2051, so that the two second welding portions 304 may be connected with the two first welding portions 2013 through the two connecting pieces 2051, respectively. As a result, the mounting substrate 201 is connected with the connecting board 3. In this way, the light-emitting group 203 may be electrically connected to the main board 500 by using a small amount of connecting pieces 2051, which is simple and convenient. Of course, the two ends of the plurality of connecting pieces 2051 may also be connected with and fixed on the mounting substrate 201 and the connecting board 3 by other means. In this way, in a case where the connecting board 3 is electrically connected to the main board 500, the light-emitting group 203 of the laser assembly 2 may be electrically connected to the main board 500, so as to receive the control signals of the main board 500 to emit the laser beams.

It will be noted that one laser assembly 2 may correspond to two connecting pieces 2051, the two connecting pieces 2051 correspond to a positive electrode and a negative electrode of a light-emitting chip 2031, respectively. In this case, the plurality of light-emitting chips 2031 of the light-emitting group 203 are connected in series with each other.

Alternatively, one laser assembly 2 may also correspond to three or more connecting pieces 2051. In this case, the plurality of light-emitting chips 2031 of the light-emitting group 203 may be connected in parallel. Moreover, the plurality of light-emitting chips 2031 may emit laser beams of different colors, and the light-emitting chips 2031 emitting laser beams of different colors may have a common anode or a common cathode. The plurality of connecting pieces 2051 may correspond to the positive electrodes and negative electrodes of the light-emitting chips 2031 emitting laser beams of different colors. Alternatively, the plurality of connecting pieces 2051 may also correspond to a group of a positive electrode and a negative electrode of the light-emitting chips 2031 emitting laser beams of each color.

In some embodiments, as shown in FIG. 13, the connecting board 3 further includes a plurality of first mounting holes 303 (i.e., a plurality of mounting holes of the second printed circuit board). The plurality of first mounting holes 303 are disposed on the plurality of second welding portions 304 (i.e., a plurality of welding portions of the second printed circuit board), respectively. The first mounting holes 303 run through the board body 300. For example, the first mounting holes 303 are through holes. Of course, the first mounting holes 303 may also not run through the board body 300. For example, the first mounting holes 303 are blind holes.

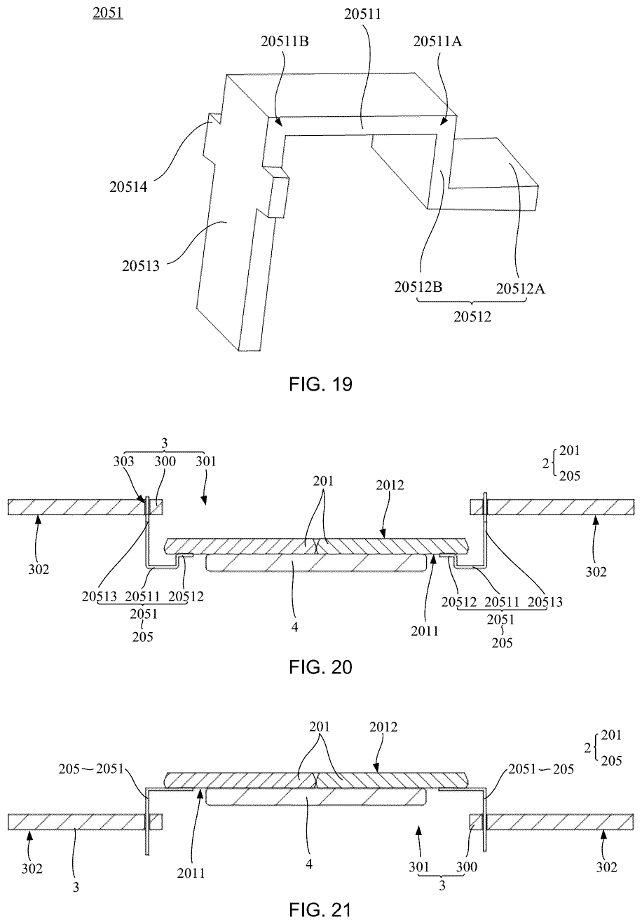

FIG. 18 is a diagram showing yet another structure of a laser assembly and a connecting board in a laser source, in accordance with some embodiments. FIG. 19 is a diagram showing a structure of a connecting piece, in accordance with some embodiments. FIG. 20 is a diagram showing yet another structure of a laser assembly and a connecting board in a laser source, in accordance with some embodiments. FIG. 21 is a diagram showing yet another structure of a laser assembly and a connecting board in a laser source, in accordance with some embodiments.

In some embodiments, as shown in FIGS. 15, 17, and 18, the connecting piece 2051 includes a main body portion 20511, a first connecting portion 20512, and a second connecting portion 20513. As shown in FIG. 19, the main body portion 20511 has a first end 20511A and a second end 20511B, and the first end 20511A and the second end 20511B are disposed opposite to each other. A first end of the first connecting portion 20512 is connected to the first end 20511A, and a second end of the first connecting portion 20512 is welded with the first welding portion 2013. For example, the first connecting portion 20512 includes a first connecting sub-portion 20512A and a second connecting sub-portion 20512B, and the first connecting sub-portion 20512A is perpendicular to the second connecting sub-portion 20512B. The first connecting sub-portion 20512A is in contact with the first welding portion 2013 and welded to the first welding portion 2013. A first end of the second connecting sub-portion 20512B is connected to the first end 20511A, and a second end of the second connecting sub-portion 20512B is connected to the first connecting sub-portion 20512A. Of course, the first connecting portion 20512 may also be in other shapes. For example, as shown in FIG. 17, the first connecting portion 20512 is in a shape of a strip and abuts against and is welded with the first welding portion 2013.

A first end of the second connecting portion 20513 is connected to the second end 20511B, and a second end of the second connecting portion 20513 is matched with the first mounting hole 303 and welded to the second welding portion 304. For example, the second connecting portion 20513 is in a shape of a strip, and the second connecting portion 20513 is inserted into the first mounting hole 303 and fixed to the second welding portion 304 by welding. In this way, in a case where the connecting piece 2051 has a set structural strength, the connecting piece 2051 may perform elastic deformation, which is helpful for the two ends of the connecting piece 2051 to be connected with the mounting substrate 201 and the connecting board 3, respectively.

In some embodiments, as shown in FIG. 19, the first connecting portion 20512 and the second connecting portion 20513 are perpendicular to the main body portion 20511. Of course, a preset angle between the first connecting portion 20512 (or the second connecting portion 20513) and the main body portion 20511 may also be acute or obtuse.

In some embodiments, in a case where the first mounting hole 303 is a through hole running through the board body 300, as shown in FIG. 19, the connecting piece 2051 further includes a protrusion 20514. The protrusion 20514 is disposed on a side of the second connecting portion 20513 and protrudes in a direction away from the second connecting portion 20513. The protrusion 20514 abuts against a surface (e.g., the third surface 302) of the board body 300, so as to limit the connecting piece 2051. For example, as shown in FIG. 19, the connecting piece 2051 includes two protrusions 20514, and the two protrusions 20514 are disposed on two sides of the second connecting portion 20513 respectively and disposed symmetrically with respect to the second connecting portion 20513. In this way, the stability of the connection between the connecting piece 2051 and the connecting board 3 may be improved by providing the protrusions 20514.

It may be understood that the mounting substrate 201 may also include a plurality of second mounting holes disposed on the plurality of first welding portions 2013 in a manner similar to the connecting manner of the first mounting holes 303 of the connecting board 3, so that the first end of the conductive connecting portion 205 may be inserted into the second mounting hole and welded with the first welding portion 2013.

It will be noted that in a case where the first surface 2011 and the third surface 302 are located in different planes, as shown in FIGS. 20 and 21, the connecting piece 2051 may still be connected to the mounting substrate 201 and the connecting board 3 by the above connecting manner.

However, in some embodiments, the connecting piece 2051 may also directly abut against the second welding portion 304 of the connecting board 3. In this case, the first mounting hole 303 is optional and may be omitted. For example, the connecting board 3 may not include the first mounting hole 303. For example, as shown in FIGS. 15 and 17, the second end of the first connecting portion 20512 of the connecting piece 2051 abuts against and is welded with the first welding portion 2013, and the second end of the second connecting portion 20513 of the connecting piece 2051 abuts against and is welded with the second welding portion 304.

Of course, the connecting piece 2051 may also have other connecting manners with the mounting substrate 201 and the connecting board 3.

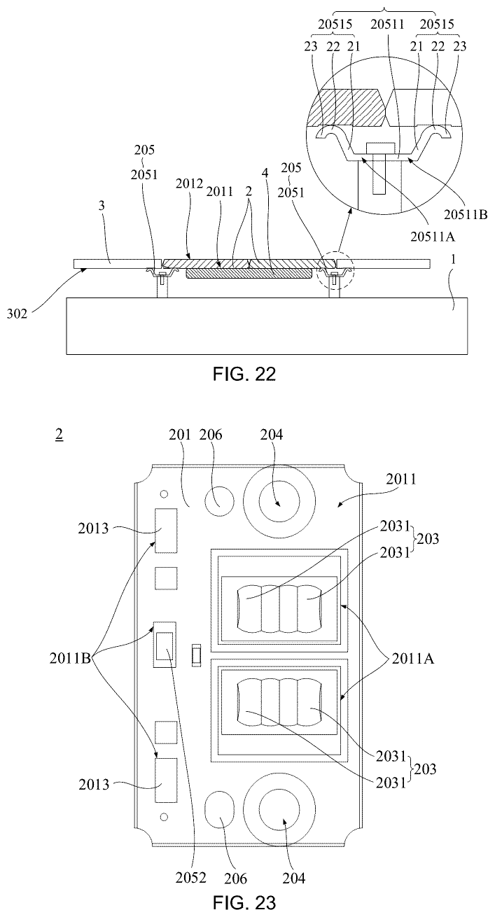

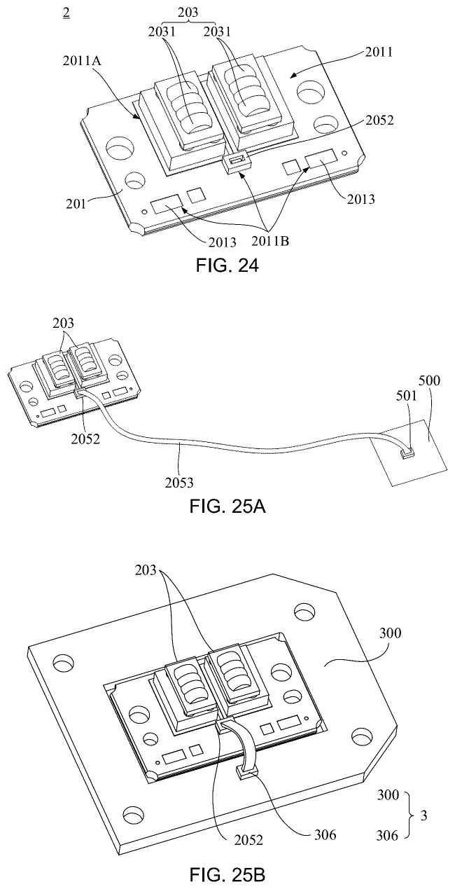

FIG. 22 is a diagram showing yet another structure of a laser assembly and a connecting board in a laser source, in accordance with some embodiments. FIG. 23 is a diagram showing a structure of another laser assembly, in accordance with some embodiments. FIG. 24 is a diagram showing a structure of yet another laser assembly, in accordance with some embodiments. FIG. 25A is a diagram showing yet another structure of a laser assembly and a connecting board in a laser source, in accordance with some embodiments. FIG. 25B is a diagram showing yet another structure of a laser assembly and a connecting board in a laser source, in accordance with some embodiments.

In some embodiments, as shown in FIG. 22, the connecting piece 2051 includes a main body portion 20511 and a plurality of third connecting portions 20515. The main body portion 20511 is connected to the housing 1 and has a first end 20511A and a second end 20511B disposed opposite to each other. The plurality of third connecting portions 20515 are connected to two ends (i.e., the first end 20511A and the second end 20511B) of the main body portion 20511, respectively, and located on a same side (e.g., a side of the main body portion 20511 away from the housing 1) of the main body portion 20511. The plurality of third connecting portions 20515 abut against the first welding portion 2013 and the second welding portion 304, respectively.

For example, as shown in FIG. 22, the laser source 10 includes two connecting pieces 2051, and one connecting piece 2051 includes two third connecting portions 20515. The third connecting portion 20515 includes a third connecting sub-portion 21, a fourth connecting sub-portion 23, and a bending portion 22. Two ends of the bending portion 22 are connected to the third connecting sub-portion 21 and the fourth connecting sub-portion 23, respectively, and a surface of the bending portion 22 away from the housing 1 abuts against and is welded with the first welding portion 2013 or the second welding portion 304. The bending portion 22 is in a shape of an arc and its arc opening is towards the housing 1. In this way, in a case where the connecting piece 2051 has a set structural strength, the connecting piece 2051 may perform elastic deformation, which is help for the connecting piece 2051 to be connected with the mounting substrate 201 and the connecting board 3 and is conducive to installation and disassembly.

In some embodiments, the third connecting portions 20515 are disposed with the main body portion 20511 at a preset angle. For example, the third connecting portions 20515 are perpendicular to the main body portion 20511. Of course, the preset angle between the third connecting portion 20515 and the main body portion 20511 may also be other angles.

It will be noted that FIG. 22 illustrates an example in which the first surface 2011 and the third surface 302 are coplanar. However, in a case where the first surface 2011 is not coplanar with the third surface 302, the connecting piece 2051 may still abut against and be welded with the mounting substrate 201 and the connecting board 3 by using the above connecting manner.

In addition, the conductive connecting portion 205 in some embodiments of the present disclosure is not limited to the connecting piece 2051, and the conductive connecting portion 205 may also be replaced by a metal wire (e.g., a gold wire, a silver wire or a copper wire). In this case, the mounting substrate 201 is connected with the connecting board 3 through the metal wire. For example, the conductive connecting portion 205 includes a connecting wire, a first end of the connecting wire is connected to the second region 2011B (e.g., the first welding portion 2013), and a second end of the connecting wire is connected to a portion (e.g., the second welding portion 304) of the connecting board 3.

In some embodiments, the conductive connecting portion 205 may also be directly electrically connected to the main board 500. In this case, there is no need to provide the connecting circuit board (e.g., the connecting board 3), and the second printed circuit board includes the main board 500.

For example, as shown in FIGS. 23 and 24, the mounting substrate 201 includes a first socket 2052, and the first socket 2052 is disposed on the first surface 2011 and located in the second region 2011B. The first socket 2052 is connected with the second region 2011B. For example, the first socket 2052 is welded to the first surface 2011 by means of the surface mounted technology.

In this case, as shown in FIG. 25A, the main board 500 is provided with a third socket 501, and the conductive connecting portion 205 includes a connecting wire 2053 (e.g., a flexible printed circuit). A first end of the connecting wire 2053 is connected to the first socket 2052, and a second end of the connecting wire 2053 is connected to the third socket 501, so that the light-emitting group 203 is electrically connected to the main board 500. It may be understood that the first or second end of the connecting wire 2053 may also be connected to the first welding portion 2013 of the mounting substrate 201 or a welding portion of the main board 500 without the socket.

Similar to the above connecting manner of the mounting substrate 201 and the main board 500 by the connecting wire 2053, the mounting substrate 201 and the connecting board 3 may also use the connecting manner shown in FIGS. 23 to 25A. In some embodiments, as shown in FIG. 25B, the laser assembly 2 may also be electrically connected to the connecting board 3 through the first socket 2052. For example, the connecting board 3 includes a second socket 306, the second socket 306 is disposed on the board body 300 and connected to the first socket 2052 by a connecting wire (e.g., a flexible printed circuit). It will be noted that in a case where the connecting board 3 includes the second socket 306, the connecting board 3 may further include the second welding portion 304.

It will be noted that the second socket 306 in FIG. 25B is only an example, and the second socket 306 may also be located at other positions of the connecting board 3, and the connecting board 3 may also include two or more second sockets 306.

It may be understood that similar to the above connecting manner of the mounting substrate 201 and the connecting board 3 by the connecting piece 2051, the mounting substrate 201 and the main board 500 may also be connected by the connecting piece 2051. Moreover, the conductive connecting portion 205 may be a component independent of the laser assembly 2. For example, the laser source 10 includes a conductive connecting portion 205.

The above description is mainly given by considering an example in which the laser source 10 includes a single laser assembly 2. Of course, in some embodiments, the laser source 10 may further include a plurality of laser assemblies 2, so as to increase the power of the laser source 10. The mounting substrates 201 of the plurality of laser assemblies 2 abut against each other and are arranged side by side, and the plurality of light-emitting groups 203 of the plurality of laser assemblies 2 each are disposed on the corresponding mounting substrate 201.

Of course, the plurality of light-emitting groups 203 of the plurality of laser assemblies 2 may also share a same mounting substrate 201. For example, the plurality of light-emitting groups 203 of the plurality of laser assemblies 2 are disposed on a same mounting substrate 201. Moreover, in a case where the plurality of laser assemblies 2 are installed on one mounting substrate 201, for the connecting manner between the mounting substrate 201 and the connecting board 3, reference may be made to the related content in the embodiments described above.

In some embodiments, as shown in FIG. 11, the laser source 10 includes a first laser assembly 2A and a second laser assembly 2B.

In the first laser assembly 2A or the second laser assembly 2B, the plurality of first welding portions 2013 are located on a same side of the light-emitting group 203. For example, the mounting substrate 201 has a rectangular shape, the light-emitting group 203 is located at a first end of the mounting substrate 201 in a width direction (e.g., a direction RS in FIG. 12), and the plurality of first welding portions 2013 are located at a second end of the mounting substrate 201 in the width direction. Moreover, in the connecting board 3, the plurality of second welding portions 304 electrically connected to a same laser assembly 2 are also located on a same side of the laser assembly 2 (e.g., the hollow region 301 or the opening).

For example, as shown in FIG. 11, the first laser assembly 2A and the second laser assembly 2B are disposed in the hollow region 301, and the plurality of second welding portions 304 are located on two sides of the hollow region 301. The second welding portions 304 electrically connected to the first laser assembly 2A are located on a first side of the hollow region 301, and the second welding portions 304 electrically connected to the second laser assembly 2B are located on a second side of the hollow region 301.

As shown in FIG. 11, the mounting substrate 201 of the first laser assembly 2A abuts against the mounting substrate 201 of the second laser assembly 2B, and the first surface 2011 of the first laser assembly 2A is coplanar with the first surface 2011 of the second laser assembly 2B. For example, an end of the mounting substrate 201 of the first laser assembly 2A proximate to the light-emitting group 203 abuts against an end of the mounting substrate 201 of the second laser assembly 2B proximate to the light-emitting group 203. Moreover, an end of the mounting substrate 201 of the first laser assembly 2A away from the light-emitting group 203 and an end of the mounting substrate 201 of the second laser assembly 2B away from the light-emitting group 203 abut against the inner wall of the hollow region 301.

In this way, the power of the illumination beams emitted by the laser source 10 may be increased by splicing the two laser assemblies 2 together and providing the two laser assemblies 2 in one hollow region 301 or one opening. It will be noted that FIG. 11 illustrates an example in which the laser source 10 includes two laser assemblies 2. Of course, the laser source 10 may also include three, four or more laser assemblies 2.

The following describes an example in which the laser source 10 includes two laser assemblies 2.

In some embodiments, as shown in FIG. 10, the housing 1 further includes a light inlet 110, and the light inlet 110 is disposed on the third side plate 103 (e.g., the first side sub-plate 1031). The light inlet 110 is communicated with the accommodating space 1000, and at least a portion of the laser assembly 2 is located in the light inlet 110. The light inlet 110 is configured to make the laser beams emitted by the laser assembly 2 pass through, so that the laser beams emitted by the laser assembly 2 are incident into the accommodating space 1000. The laser beams incident into the accommodating space 1000 may propagate to the light outlet 104 through the lens group and the reflecting lens group and be incident into the light modulation assembly 20 through the light outlet 104.

In some embodiments, as shown in FIG. 10, in a case where the laser source 10 includes two laser assemblies 2, the light inlet 110 includes a third mounting hole 105 and a fourth mounting hole 106. The third mounting hole 105 and the fourth mounting hole 106 are disposed on the first side sub-plate 1031, and at least a portion of the first laser assembly 2A and at least a portion of the second laser assembly 2B are disposed in the third mounting hole 105 and the fourth mounting holes 106, respectively.

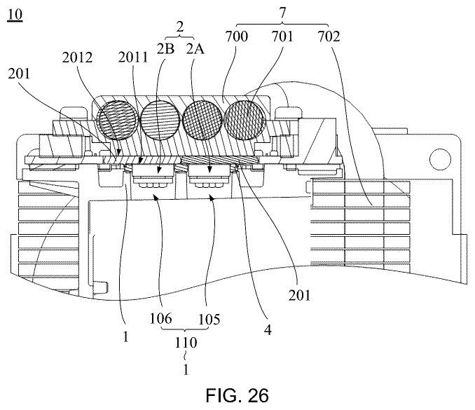

FIG. 26 is a diagram showing a structure of another laser source, in accordance with some embodiments. For example, as shown in FIG. 26, an inner wall of the third mounting hole 105 surrounds the light-emitting group 203 in the first laser assembly 2A, and an inner wall of the fourth mounting hole 106 surrounds the light-emitting group 203 in the second laser assembly 2B.

In this case, in order to seal the laser source 10 and improve the airtight characteristic of the accommodating space 1000 in the housing 1, as shown in FIG. 26, the laser source 10 further includes a closing member 4. The closing member 4 may be made of silica gel and have high heat resistance. The closing member 4 is located between the housing 1 and the mounting substrate 201 and abuts against the housing 1 and the mounting substrate 201, so as to close gaps between the housing 1 and the mounting substrate 201.

In this way, the closing member 4 is squeezed by the mounting substrate 201 of the laser assembly 2 and the housing 1, which may seal the housing 1 of the laser source 10 and be conducive to installation and disassembly. For example, as shown in FIG. 11, the closing member 4 includes a closing body 400, a first through hole 401, and a second through hole 402. The first through hole 401 and the second through hole 402 are disposed on the closing body 400, and an inner wall of the first through hole 401 surrounds the light-emitting group 203 of the first laser assembly 2A, and an inner wall of the second through hole 402 surrounds the light-emitting group 203 of the second laser assembly 2B.

In some embodiments, the first through hole 401 and the second through hole 402 are arranged at an interval. In this way, the closing member 4 may seal the first laser assembly 2A and the second laser assembly 2B, which improves the sealing effect and is conducive to reducing the volume of the closing member 4.

In some embodiments, as shown in FIG. 10, the housing 1 further includes a support portion 109. The support portion 109 is disposed on the third side plate 103, and at least a portion of at least one of the laser assembly 2 or the connecting board 3 is disposed on the support portion 109.

For example, as shown in FIG. 10, the support portion 109 includes a first support portion 107 and a second support portion 108. The first support portion 107 and the second support portion 108 are disposed on the first side sub-plate 1031, and the second support portion 108 is disposed around the first support portion 107. The laser assembly 2 is disposed on the first support portion 107, and the connecting board 3 is disposed on the second support portion 108.

In some embodiments, as shown in FIG. 10, the first support portion 107 includes a first boss 107A and a second boss 107B, and the first boss 107A and the second boss 107B are disposed opposite to each other. The two bosses protrude in a direction away from the first side sub-plate 1031, and surfaces (e.g., top surfaces) of the two bosses away from the first side sub-plate 1031 are coplanar. The top surfaces of the two bosses abut against the first surface 2011 of the mounting substrate 201 of the laser assembly 2, so as to carry the laser assembly 2.

The second support portion 108 includes a plurality of threaded columns. The plurality of threaded columns are disposed on the first side sub-plate 1031. Surfaces (e.g., top surfaces) of the plurality of threaded columns away from the first side sub-plate 1031 are coplanar, and the top surfaces of the threaded columns abut against the third surface 302, so as to carry the connecting board 3. Moreover, the connecting board 3 may be fixed to the plurality of threaded columns by fasteners (e.g., screws).

In some embodiments, the light inlet 110 is located between the two bosses (i.e., the first boss 107A and the second boss 107B). For example, as shown in FIG. 10, in a case where the laser source 10 includes two laser assemblies 2, the two bosses are located on two sides of the light inlet 110 formed by the third mounting hole 105 and the fourth mounting hole 106, respectively, and are proximate to the light inlet 110. Moreover, the minimum distance between each boss and the inner wall of the light inlet 110 is the same as a thickness of a portion of the closing body 400 between the boss and the light inlet 110.

For example, the minimum distance between the inner wall of the first through hole 401 and an outer side wall of the closing body 400 of the closing member 4 is the same as the minimum distance between the first boss 107A (or the second boss 107B) and the inner wall of the light inlet 110. In this way, the two bosses may limit the closing member 4 and improve the sealing reliability of the closing member 4.

In some embodiments, as shown in FIG. 10, the housing 1 includes a plurality of first threaded holes 1071, and the plurality of first threaded holes 1071 are disposed on the first support portion 107. As shown in FIG. 12, the laser assembly 2 includes a plurality of fifth mounting holes 204. The plurality of fifth mounting holes 204 are disposed on the mounting substrate 201 and correspond to the plurality of first threaded holes 1071 respectively.

In this case, as shown in FIGS. 8 and 9, the laser source 10 includes a plurality of fixing members 5. The fixing member 5 runs through the fifth mounting hole 204 and is fixedly connected to the first threaded hole 1071, so as to install the laser assembly 2 on the housing 1. For example, as shown in FIG. 12, the plurality of fifth mounting holes 204 include two fifth mounting holes 204, and the two fifth mounting holes 204 are symmetrically disposed at two ends of the mounting substrate 201 in a length direction (e.g., a direction JK in FIG. 12). In a case where the laser source 10 includes two laser assemblies 2, the housing 1 includes four first threaded holes 1071 and four fixing members 5, and the four first threaded holes 1071 and the four fixing members 5 correspond to the four fifth mounting holes 204 in the two laser assemblies 2.

In some embodiments, the fixing member 5 includes a screw. A threaded rod of the screw passes through the fifth mounting hole 204 and is connected with the first threaded hole 1071 in a threaded manner, and a nut of the screw abuts against the second surface 2012 of the mounting substrate 201.

In some embodiments, as shown in FIG. 12, the laser assembly 2 further includes a plurality of first positioning portions 206, and the plurality of first positioning portions 206 are disposed on the mounting substrate 201. The housing 1 further includes a plurality of second positioning portions 6 (as shown in FIG. 10). The plurality of second positioning portions 6 are disposed on the third side plate 103 and are matched with the plurality of first positioning portions 206 respectively.

For example, as shown in FIG. 12, the laser assembly 2 includes two first positioning portions 206, and the two first positioning portions 206 are symmetrically disposed at two ends of the mounting substrate 201 in the length direction. In a case where the laser source 10 includes two laser assemblies 2, the housing 1 includes four second positioning portions 6 corresponding to the four first positioning portions 206 of the two laser assemblies 2.

In this way, when the laser assembly 2 is installed on the housing 1, the second positioning portions 6 may be matched with the first positioning portions 206, so as to preposition the laser assembly 2, and then the laser assembly 2 is fixed on the housing 1 through the fixing member 5, which is conducive to the installation between the laser assembly 2 and the housing 1.

In some embodiments, one of the first positioning portion 206 and the second positioning portion 6 is a positioning column, and another of the first positioning portion 206 and the second positioning portion 6 is a positioning hole.

In some embodiments, as shown in FIG. 26, the laser source 10 further includes a radiator 7. The radiator 7 is connected to the housing 1 and in contact with the second surface 2012. In this way, the laser assembly 2 may be cooled by the radiator 7, so that the laser assembly 2 operates normally.

For example, the radiator 7 includes a heat conducting portion 700, a heat conducting pipe 701, and heat dissipation fins 702. A first end of the heat conducting pipe 701 is connected to the heat conducting portion 700, and a second end of the heat conducting pipe 701 is connected to the heat dissipation fins 702. The heat conducting portion 700 is disposed on a side of the laser assembly 2 away from the housing 1 and in contact with the mounting substrate 201, so as to dissipate heat of the laser assembly 2. It will be noted that a portion of the heat conducting pipe 701 is disposed in the heat conducting portion 700. Of course, the radiator 7 may further include a cooling head and a cooling row communicated with each other, and the cooling head is in contact with the second surface 2012, so as to cool the laser assembly 2.

In some embodiments, as shown in FIG. 9, the laser source 10 further includes a plurality of damping members 8 (e.g., the sound-absorbing foam) located on two sides of the connecting board 3 in a thickness direction (e.g., a direction UD in FIG. 9). The plurality of damping members 8 are configured to reduce the noise generated by the laser source 10. FIG. 9 illustrates an example in which the laser source 10 includes two damping members 8, and the two damping members 8 are disposed on two sides of the connecting board 3 respectively. Of course, the laser source 10 may also include one, three, or more damping members 8, and the damping members 8 may also be other components with noise reducing function and disposed at other positions of the laser source 10, and the present disclosure is not limited thereto.

In the above description of the embodiments, specific features, structures, materials, or characteristics may be combined in a suitable manner in any one or more embodiments or examples.

It will be noted that any one of the technical solutions disclosed in the present disclosure may solve one or more of the technical problems described above and achieve certain disclosure purposes to a certain extent; a plurality of disclosed technical solutions may also be combined into an overall solution, so as to solve one or more of the technical problems described above and achieve certain disclosure purposes; some technical disclosures may also be selected to be combined into an overall solution, while adopting the related art and deteriorated solutions, but the deterioration trend may be compensated by means of the present technical disclosure, and one or more of the technical problems described above may be solved to a certain extent as a whole and certain disclosure purposes may be achieved to a certain extent as a whole; and the technical disclosure combined into a complete technical solution constitutes an organic and inseparable overall solution, which solves technical problems as a whole and achieves certain disclosure purposes.

Any technical disclosure in the present disclosure, as well as the recombination of the plurality of technical disclosures, may form a complete technical solution and solve one or more of the technical problems described above and achieve the disclosure purposes. They all belong to the content of the present disclosure and belong to the content that is directly and unambiguously determined according to the content of the present disclosure.

A person skilled in the art will understand that the scope of disclosure in the present disclosure is not limited to specific embodiments discussed above and may modify and substitute some elements of the embodiments without departing from the spirits of the present disclosure. The scope of the present disclosure is limited by the appended claims.

What is claimed is:

1. A laser source, comprising:
at least one laser assembly, including:
a mounting substrate, the mounting substrate being a first printed circuit board (PCB) and including:
a first surface;
a first region located on the first surface; and
a second region located on the first surface, the first region and the second region being discontinuously distributed, and the first region being connected with the second region through an internal wiring of the mounting substrate;
at least one light-emitting group disposed on the first surface and located in the first region, the light-emitting group being electrically connected with the first region, the light-emitting group including a plurality of light-emitting chips and being configured to emit laser beams; and
at least one conductive connecting portion, a first end of the conductive connecting portion being connected with the second region, and a second end of the conductive connecting portion being configured to be electrically connected with a second printed circuit board, so as to electrically connect the light-emitting group with the second printed circuit board.

2. The laser source according to claim 1, further comprising a connecting board, the second printed circuit board including the connecting board, the connecting board being configured to be electrically connected with a main board, wherein the two ends of the conductive connecting portion are welded with the second region of the mounting substrate and the connecting board, respectively, and the laser assembly is connected with the connecting board through the conductive connecting portion.

3. The laser source according to claim 2, wherein the second region is located at an edge of the mounting substrate, and the second region is closer to the connecting board than the first region;
the mounting substrate includes a plurality of first welding portions, the plurality of first welding portions constitute the second region;
the connecting board includes a board body and a plurality of second welding portions, the plurality of second welding portions are disposed on the board body; and
the at least one conductive connecting portion includes a plurality of conductive connecting portions, the plurality of conductive connecting portions correspond to the plurality of first welding portions and the plurality of second welding portions respectively; the first end of any of the plurality of conductive connecting portions is connected to any of the plurality of first welding portions, and the second end of the conductive connecting portion is connected to any of the plurality of second welding portions.

4. The laser source according to claim 3, wherein the conductive connecting portion satisfies one of following:
the conductive connecting portion includes a connecting piece, and a first end of the connecting piece is connected to any of the plurality of first welding portions, and a second end of the connecting piece is connected to any of the plurality of second welding portions; and
the conductive connecting portion includes a connecting wire, a first end of the connecting wire is connected to the first welding portion, and a second end of the connecting wire is connected to the second welding portion.

5. The laser source according to claim 3, wherein
the plurality of first welding portions are located on a same side of the corresponding light-emitting group, the plurality of second welding portions connected with a same laser assembly are located on a same side of the laser assembly.

6. The laser source according to claim 1, wherein the first end of the conductive connecting portion abuts against and is welded with the second region of the mounting substrate, and the second end of the conductive connecting portion abuts against and is welded with a welding portion of the second printed circuit board.

7. The laser source according to claim 1, wherein the conductive connecting portion further satisfies one of following:
the second printed circuit board includes a plurality of mounting holes and a plurality of welding portions, the plurality of mounting holes are disposed on the plurality of welding portions of the second printed circuit board, respectively, the mounting substrate further includes a plurality of first welding portions, the first end of the conductive connecting portion abuts against and is welded with any of the plurality of first welding portions, and the second end of the conductive connecting portion is inserted into any of the plurality of mounting holes and welded with the welding portion of the second printed circuit board; and
the second printed circuit board includes the plurality of mounting holes and the plurality of welding portions, the plurality of mounting holes are disposed on the plurality of welding portions of the second printed circuit board, respectively, the mounting substrate further includes a plurality of first welding portions and a plurality of second mounting holes, the plurality of second mounting holes are disposed on the plurality of first welding portions, respectively, the first end of the conductive connecting portion is inserted into any of the plurality of second mounting holes and welded with the first welding portion, and the second end of the conductive connecting portion is inserted into any of the plurality of mounting holes and welded with the welding portion of the second printed circuit board.

8. The laser source according to claim 1, wherein at least one of the second printed circuit board or the mounting substrate includes a socket, and the conductive connecting portion includes a connecting wire, and the conductive connecting portion satisfies one of following:
a first end of the connecting wire is connected to the socket of the mounting substrate, and a second end of the connecting wire is connected to the socket of the second printed circuit board, so as to connect the second printed circuit board with the mounting substrate;
the first end of the connecting wire is connected to a first welding portion of the mounting substrate, and the second end of the connecting wire is connected to the socket of the second printed circuit board, so as to connect the second printed circuit board with the mounting substrate; and
the first end of the connecting wire is connected to the socket of the mounting substrate, and the second end of the connecting wire is connected to a welding portion of the second printed circuit board, so as to connect the second printed circuit board with the mounting substrate.

9. The laser source according to claim 8, further comprising a connecting board, the second printed circuit board including the connecting board, the connecting board being configured to be electrically connected with a main board, wherein
the mounting substrate includes a first socket, and the first socket is located in the second region and connected with the second region;
the connecting board includes a board body and a second socket, and the second socket is disposed on the board body; and
the first end of the connecting wire is connected to the first socket, and the second end of the connecting wire is connected to the second socket, so as to connect the mounting substrate with the connecting board.

10. The laser source according to claim 8, wherein
the mounting substrate includes a first socket, and the first socket is located in the second region and connected with the second region;
the second circuit board includes a main board, and the main board is provided with a third socket; and
the first end of the connecting wire is connected to the first socket, and the second end of the connecting wire is connected to the third socket, so as to electrically connect the light-emitting group with the main board.

11. The laser source according to claim 1, further comprising a connecting board, the second printed circuit board including the connecting board, the connecting board being configured to be electrically connected with a main board, wherein the connecting board satisfies one of following:
the connecting board includes:
a board body having a third surface; and
a hollow region disposed on the board body and running through the board body, an orthogonal projection of the laser assembly on the board body at least overlapping the hollow region; and
the connecting board includes:
the board body having a third surface; and
an opening, a side of the board body in a direction perpendicular to a thickness direction of the board body being concave inward to provide the opening, and the orthogonal projection of the laser assembly on the board body at least overlapping the opening.

12. The laser source according to claim 11, wherein a light-emitting surface of the light-emitting group, the mounting substrate, and the connecting board are parallel to each other.

13. The laser source according to claim 12, wherein the mounting substrate is arranged side by side with the connecting board.

14. The laser source according to claim 12, wherein the first surface and the third surface are in different planes.

15. The laser source according to claim 1, wherein at least one of the light-emitting group includes a plurality of light-emitting groups, and the plurality of light-emitting groups satisfy one of following:
the plurality of light-emitting groups are configured to emit the laser beams of different colors, two or more light-emitting groups emitting the laser beams of a same color are connected in series, and two or more light-emitting groups emitting the laser beams of different colors are connected in parallel with each other; and
the plurality of light-emitting groups are configured to emit the laser beams of a same color and connected in series.

16. The laser source according to claim 1, further comprising:
a housing; and
a closing member located between the housing and the mounting substrate and abutting against the housing and the mounting substrate, so as to close gaps between the housing and the mounting substrate.

17. The laser source according to claim 16, wherein the at least one laser assembly includes a plurality of laser assemblies, and the plurality of laser assemblies satisfy one of following:
the plurality of laser assemblies include a plurality of mounting substrates, the plurality of mounting substrates are connected to each other, and the plurality of light-emitting groups of the plurality of laser assemblies each are disposed on the corresponding mounting substrate; and
the plurality of laser assemblies include one mounting substrate, and the plurality of light-emitting groups of the plurality of laser assemblies are disposed on a same mounting substrate.

18. The laser source according to claim 17, wherein
the plurality of laser assemblies include a first laser assembly and a second laser assembly, the first laser assembly and the second laser assembly satisfy one of following: the mounting substrate of the first laser assembly abuts against the mounting substrate of the second laser assembly; and the plurality of light-emitting groups of the first laser assembly and the second laser assembly are disposed on a same mounting substrate;
the closing member includes:
a closing body;
a first through hole disposed on the closing body, an inner wall of the first through hole surrounding the light-emitting group of the first laser assembly; and
a second through hole disposed on the closing body, an inner wall of the second through hole surrounding the light-emitting group of the second laser assembly.

19. The laser source according to claim 16, wherein
the laser assembly further includes a plurality of first positioning portions disposed on the mounting substrate;
the housing includes:
a housing body;
a support portion disposed on the housing body, at least a portion of at least one of the laser assembly or the second printed circuit board being disposed on the support portion; and
a plurality of second positioning portions disposed on the housing body, the plurality of second positioning portions being matched with the plurality of first positioning portions respectively, so as to position the laser assembly.

20. A laser projection apparatus, comprising:
a laser source configured to emit illumination beams;
a light modulation assembly configured to modulate the illumination beams emitted by the laser source, so as to obtain projection beams;
a projection lens configured to project the projection beams into an image; and
a main board configured to transmit a control signal, so as to control the laser projection apparatus for image display;
wherein the laser source includes:
a housing; and
a laser assembly disposed on the housing, a light-emitting side of the laser assembly being towards an interior of the housing, and the laser assembly including:
a mounting substrate, the mounting substrate being a first printed circuit board and including:
a first surface, the first surface being a surface of the mounting substrate proximate to the housing;
a first region located on the first surface; and
a second region located on the first surface, the first region and the second region being discontinuously distributed, and the first region being connected with the second region through an internal wiring of the mounting substrate;
a light-emitting group disposed on the first surface and located in the first region, the light-emitting group being electrically connected with the first region, and the light-emitting group including a plurality of light-emitting chips and being configured to emit laser beams; and
a conductive connecting portion, a first end of the conductive connecting portion being connected with the second region, and a second end of the conductive connecting portion being configured to be electrically connected with a second printed circuit board, so as to electrically connect the light-emitting group with the main board.
